(19) United States
(12) Patent Application Publication
(10) Pub. No.: US 2012/0328885 A1
(43) Pub. Date: Dec. 27, 2012

(54) DEPOSITION OF POLYMER FILMS BY ELECTROSPINNING

(75) Inventor: SUKTI CHATTERJEE, Cupertino, CA (US)

(73) Assignee: APPLIED MATERIALS, INC., Santa Clara, CA (US)

(21) Appl. No.: 13/524,263

(22) Filed: Jun. 15, 2012

Related U.S. Application Data
(60) Provisional application No. 61/499,277, filed on Jun. 21, 2011.

(51) Int. Cl. B05D 1/04; B32B 5/02; C09D 139/06; B05C 11/10; H01L 23/58; C09D 127/18; B32B 17/12; B05C 5/00

(52) U.S. Cl. 428/426; 427/458; 118/300; 118/620; 257/629; 524/546; 524/548; 257/E23.001

(57) ABSTRACT

Methods and apparatus for depositing polymer films are provided herein. In some embodiments a method for depositing a dielectric film may include flowing a liquid polymer precursor material through an orifice spaced apart from a substrate upon which the liquid polymer precursor material is to be deposited; providing a potential difference between the orifice and the substrate to attract the liquid polymer towards the substrate and form a deposited material on the substrate; and curing the deposited material to form a dielectric film on the substrate.

### CROSS-REFERENCE TO RELATED APPLICATIONS

This application claims benefit of U.S. provisional patent application Ser. No. 61/499,277, filed Jun. 21, 2011, which is herein incorporated by reference in its entirety.

### FIELD

Embodiments of the present invention generally relate to the deposition of polymer films.

### BACKGROUND

In microelectronic devices, the capacitive resistance of an interconnect array elevates signal delay and power consumption. To reduce such problems, insulating materials with low dielectric constants are required, preferably materials with a dielectric constant of less than 2. Electrospinning, a technique used in the textile manufacturing field and in the medical field (wound dressing, implant materials), is a cost effective method of producing long, continuous nanofibers though an electrically charged jet of polymer solution or polymer melt. However, electrospinning is generally not used to produce films.

Accordingly, the inventors have provided improved methods and apparatus for deposition of ultra low-k polymer films by electrospinning.

### SUMMARY

Methods and apparatus for depositing polymer films are provided herein. In some embodiments a method for depositing a dielectric film may include flowing a liquid polymer precursor material through an orifice spaced apart from a substrate upon which the liquid polymer precursor material is to be deposited; providing a potential difference between the orifice and the substrate to attract the liquid polymer towards the substrate and form a deposited material on the substrate; and curing the deposited material to form a dielectric film on the substrate.

In some embodiments, an ultra-low K dielectric film may include a plurality of cured nanofibers forming a film having a dielectric constant value of less than 2. In some embodiments, the ultra-low K dielectric film may be produced by the methods disclosed herein.

In some embodiments, an apparatus for depositing a dielectric film may include a chamber body defining an inner volume; a substrate support disposed in the inner volume; a reservoir coupled to the chamber body to hold a liquid polymer precursor material; and an orifice coupled to the reservoir, wherein the orifice projects downward into the inner volume of the chamber body over the substrate support.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for depositing polymer films in accordance with some embodiments of the present invention.

FIG. 2 depicts an apparatus equipped to deposit polymer films in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

The present invention generally relates to methods for the deposition of polymer films. Embodiments of the inventive method may be used to deposit dielectric polymer films having any dielectric constant. However, embodiments of the inventive methods may advantageously facilitate the deposition of polymer films having a low dielectric constant, or k. In some embodiments, the inventive methods may be used to advantageously deposit polymer films having an ultra-low dielectric constant. As used herein a low dielectric constant corresponds to a k value of between about 2 to about 3.9, and an ultra-low dielectric constant corresponds to a k value of less than about 2.

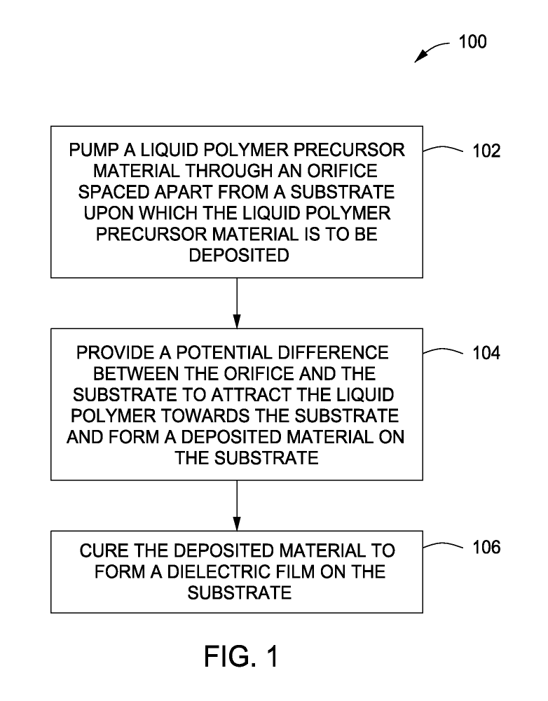

FIG. 1 is a flow diagram of a method for depositing polymer films in accordance with some embodiments of the present invention. The method 100 begins at step 102, wherein a liquid polymer precursor material is flowed through an orifice spaced apart from a substrate upon which the liquid polymer precursor material is to be deposited. The liquid polymer precursor material may be pumped through the orifice to provide a desired flow rate, diameter of the liquid polymer precursor material exiting the orifice, or the like. The substrate may be, for example, a semiconductor substrate, a glass panel, or part of an electronic device being fabricated on the substrate.

The method 100 continues at step 104, wherein a potential difference is created between the orifice and the substrate to attract the liquid polymer precursor material towards the substrate, thereby forming a deposited material on the substrate. In some embodiments, the deposited material may be in the form of nanofibers. In some embodiments, the nanofibers are smooth and uniform. The orifice and the substrate may be moved relative to each other to control the properties and distribution of the deposited material on the substrate, as discussed below.

The method 100 generally concludes at step 106, wherein the deposited material is cured to form a dielectric film on the substrate. In some embodiments, the dielectric film formed from the deposited nanofibers has fully interconnected multi-fibrous layers with micro/nano pores. The dielectric film deposited on the substrate has a dielectric constant, k. The density and diameter of the nanofibers affects the k value of the dielectric film. Generally, the greater the radius of the nanofibers, the lower the k value of the dielectric film and the lower the radius of the nanofibers, the higher the k value of the dielectric film In some embodiments, the k value of the dielectric film is less than 2. In some embodiments, the dielectric film may be used as part of, for example as a layer in, a microelectronic device.

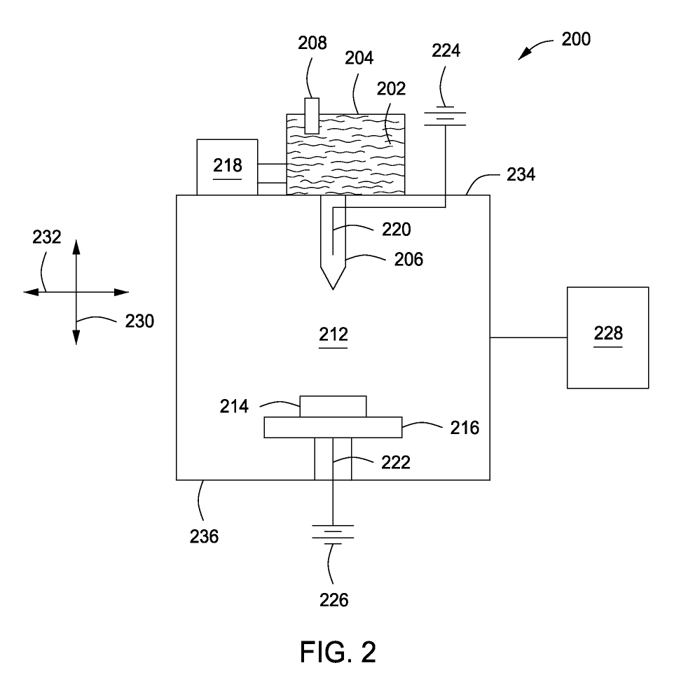

FIG. 2 depicts an apparatus 200 equipped to deposit polymer films in accordance with some embodiments of the present invention. The apparatus 200 includes a chamber body 210 defining an inner volume 212; a reservoir 204 coupled to the chamber body 210; an orifice 206 coupled to the reservoir 204, wherein the orifice 204 projects downward into the inner volume 212 of the chamber body 210; and a substrate 214 disposed upon a substrate support 216 coupled to a bottom wall 236 of the chamber body 210.

In some embodiments, the reservoir 204 is coupled to the upper wall 256 of the chamber body 210. The reservoir 204 holds a liquid polymer precursor material 202. The liquid polymer precursor material 202 is a polymer such as polytetrafluoroethylene (PTFE), polyvinylpyrrolidone (PVP), or the like, mixed with a suitable solvent such as water or other suitable solvent dependent upon the liquid polymer precursor material 202. In some embodiments, the reservoir 204 is a container that may be sealed in a pressure tight manner. In some embodiments, a temperature sensor 208 may be positioned within the reservoir 204 to measure the temperature of the liquid polymer precursor material 202 inside the reservoir 204. In some embodiments, the liquid polymer precursor material 202 may be stored in the reservoir 204 at room temperature. In some embodiments, heating and cooling coils (not shown), carrying a heat transfer fluid, may be wrapped around the exterior of the reservoir 204 to control the temperature and viscosity of the liquid polymer precursor material 202 within the reservoir 204. The heat transfer fluid may be a gas, such as helium (He), oxygen (O₂), or the like, or a liquid, such as water, antifreeze, or an alcohol, for example, glycerol, ethylene glycerol, propylene, methanol, or the like.

In some embodiments, an orifice 206 is coupled to the reservoir 204, wherein the orifice 204 projects downward into the inner volume 212 of the chamber body 210. In some embodiments, the orifice 204 is a hollow nozzle, such as a needle, pipette or syringe. In some embodiments, a pump 218 is attached to the reservoir 204 to force liquid polymer precursor material 202 through the orifice 206. In some embodiments, the diameter of the opening of the orifice 206 may be controlled to control the diameter of the nanofibers. In some embodiments, a plurality of orifices may be connected to the reservoir 204.

In some embodiments, the substrate 214 may be a semiconductor substrate, a glass panel, or part of an electronic device being fabricated on the substrate. In some embodiments, the substrate 214 is positioned on a substrate support 216 disposed within the inner volume 212 of the chamber body 210. The substrate 214 is positioned below the orifice 206. The distance between the substrate 214 and the orifice 204 must be sufficient to allow the solvent in the liquid polymer precursor material 202 to evaporate in time for the nanofibers to form. The material will be deposited in a droplet-like form on the substrate 214 as the substrate 214 is positioned closer to the orifice 206. The material will be deposited in a fiber-like form on the substrate 214 as the substrate 214 is positioned farther away from the orifice 206.

In some embodiments, the substrate support 216 may include a mechanism that retains or supports the substrate 214 on the surface of the substrate support 216, such as an electrostatic chuck, a vacuum chuck, a substrate retaining clamp, or the like (not shown). In some embodiments, the substrate support 216 may include heating or cooling coils (not shown), carrying a heat transfer fluid as described above, for controlling the substrate temperature.

In some embodiments, the orifice 206 and/or the substrate support 216 may be coupled to a mechanism for moving the orifice 206 and/or the substrate support 216 with respect to each other. For example, a pneumatic, hydraulic, electric, or manually operated actuator, motor, or the like, may be provided in either or both of the orifice 206 and the substrate support 216 to provide either or both of horizontal or vertical motion. For example, in some embodiments, the orifice 206 and/or the substrate support 216 may be movable along the first direction 232 in the horizontal plane such that the material deposited on the substrate from the orifice 206 can be distributed about the substrate disposed on the substrate support. In some embodiments, the orifice 206 and/or the substrate support 216 may be movable along the second direction 230 in the vertical plane, such as along a vertical axis, to control the spacing between the orifice 206 and the substrate support 216.

In some embodiments, the orifice 206 is connected to a first electrode 220 and the substrate support 216 is connected to a second electrode 222. A potential difference between the first electrode and second electrode creates an electrostatic field between the two electrodes 220, 222 which draws liquid polymer precursor material 202 from the reservoir 204 toward the substrate 214. In some embodiments, the first electrode 220 may be connected to a first power source 224. In some embodiments, the second electrode 222 may be connected to a second bias power source 226.

In some embodiments, a controller 228 may be coupled to the apparatus 200 to facilitate control of the apparatus 200. The controller 228 may be one of any form of general-purpose computer processor that can be used in an industrial setting for controlling various chambers and sub-processors. The controller may be control the apparatus as described above to facilitate fabrication of a desired material.

While the foregoing is directed to embodiments of the present invention, other and further embodiments of the invention may be devised without departing from the basic scope thereof.

1. A method for depositing a dielectric film, comprising:
flowing a liquid polymer precursor material through an orifice spaced apart from a substrate upon which the liquid polymer precursor material is to be deposited;
providing a potential difference between the orifice and the substrate to attract the liquid polymer towards the substrate and form a deposited material on the substrate; and
curing the deposited material to form a dielectric film on the substrate.

2. The method of claim 1, further comprising:
disposing the substrate upon a substrate support prior to flowing the liquid polymer precursor material through the orifice.

3. The method of claim 2, further comprising:
connecting a first electrode to the orifice and connecting a second electrode to the substrate support to create a potential difference between the orifice and the substrate support.

4. The method of claim 1, further comprising:
curing the deposited material to form a dielectric film with a dielectric constant of less than 2.

5. The method of claim 1, wherein the liquid polymer is deposited on the substrate as a fiber, and wherein overlapping strands of fibers form the dielectric film.

6. The method of claim 1, wherein the dielectric film comprises at least one of polytetrafluoroethylene or polyvinylpyrrolidone.

7. The method of claim 1, further comprising:
moving the orifice in at least one of a vertical or a horizontal direction while the liquid polymer precursor is flowed through the orifice.

8. The method of claim 1, wherein the substrate is disposed upon a substrate support and further comprising:
moving the substrate support in at least one of a vertical or a horizontal direction while the liquid polymer precursor is flowed through the orifice.

9. The method of claim 1, further comprising:
flowing the liquid polymer precursor material through the orifice at room temperature.

10. The method of claim 1, further comprising:
flowing the liquid polymer precursor material through a plurality of orifices spaced apart from the substrate.

11. An ultra-low K dielectric film, comprising:
a plurality of cured nanofibers forming a film having a dielectric constant value of less than 2.

12. The ultra-low K dielectric film of claim 11, further comprising:
a substrate having the plurality of cured nanofibers deposited thereon.

13. The ultra-low K dielectric film of claim 12, wherein the substrate comprises a semiconductor substrate, a glass panel, or part of an electronic device.

14. The ultra-low K dielectric film of claim 11, wherein the nanofibers are comprised of polytetrafluoroethylene, or polyvinylpyrrolidone.

15. An apparatus for depositing a dielectric film, comprising:
a chamber body defining an inner volume;
a substrate support disposed in the inner volume;
a reservoir coupled to the chamber body to hold a liquid polymer precursor material; and
an orifice coupled to the reservoir, wherein the orifice projects downward into the inner volume of the chamber body over the substrate support.

16. The apparatus of claim 15, further comprising:
a selectably sealable opening in a side wall of the chamber body to facilitate entry and egress of a substrate to the substrate support.

17. The apparatus of claim 15, further comprising:
a first electrode coupled to the orifice; and
a second electrode coupled to the substrate support to create a potential difference between the orifice and the substrate support during processing

18. The apparatus of claim 15, further comprising:
a pump coupled to the reservoir to pump the liquid polymer precursor material through the orifice.

19. The apparatus of claim 15, further comprising:
a plurality of orifices coupled to the reservoir and projecting downward into the inner volume of the chamber body over the substrate support.

20. The apparatus of claim 15, wherein at least one of the substrate support or the orifice is movable with respect to each other in at least one of a horizontal direction or a vertical direction.
